(19) United States
(12) Patent Application Publication
(10) Pub. No.: US 2025/0017055 A1
(43) Pub. Date: Jan. 9, 2025

(54) DISPLAY DEVICE AND MANUFACTURING METHOD THEREOF

(71) Applicant: Samsung Display Co., Ltd., Yongin-Si (KR)

(72) Inventor: Chun Gi YOU, Yongin-si (KR)

(21) Appl. No.: 18/750,103

(22) Filed: Jun. 21, 2024

(30) Foreign Application Priority Data
Jul. 4, 2023 (KR) 10-2023-0086429

(51) Int. Cl. H10K 59/124; H01L 29/167; H01L 29/66; H10K 59/12

(52) U.S. Cl. CPC H10K 59/124; H01L 29/167; H01L 29/6675; H10K 59/1201

(57) ABSTRACT

A method of manufacturing a display device according to an embodiment of the present invention includes forming amorphous silicon on a substrate and forming a conductive protective layer on the amorphous silicon, doping with fluorine and removing the conductive protective layer.

### CROSS-REFERENCE TO RELATED APPLICATION

This application claims priority to and the benefit of Korean Patent Application No. 10-2023-0086429 filed at the Korean Intellectual Property Office on Jul. 4, 2023, the entire contents of which are incorporated herein by reference.

### BACKGROUND

### (a) Field of the Invention

This disclosure relates to a display device and a manufacturing method of the display device.

### (b) Description of the Related Art

A display device is a device that displays an image, and recently, organic light emitting diode displays, which are a kind of light emitting display device, are attracting attention. A light emitting display device is self-luminous and, unlike a liquid crystal display device, does not require a separate light source, so a light emitting display device may be made thinner and lighter than a typical liquid crystal display device. In addition, light emitting display devices generally exhibit high quality characteristics such as low power consumption, high luminance, and high response speed.

In general, a light emitting display device includes a substrate, a plurality of thin film transistors disposed on the substrate, a plurality of insulating layers disposed on or between structures constituting the thin film transistors, and an organic light emitting element connected to the thin film transistors. A light emitting display device generally includes a plurality of pixels, and each pixel includes a plurality of transistors. Transistors may include polycrystalline semiconductors. In order to form a polycrystalline semiconductor, an amorphous semiconductor undergoes a crystallization step through heat treatment such as may be applied using a laser.

### SUMMARY

Embodiments disclosed herein may provide a method for manufacturing a display device and may prevent generation of static electricity during fluorine doping. Embodiments may also include a display device manufactured by the method.

A manufacturing method of a display device according to an embodiment of the present disclosure includes forming amorphous silicon on a substrate and forming a conductive protective layer on the amorphous silicon, doping with fluorine and removing the conductive protective layer.

The method may further include crystallizing the amorphous silicon after removing the conductive protective layer.

Forming an insulating film on the substrate may be further included prior to forming the amorphous silicon on the substrate.

The conductive protective layer may include a metal, and the metal may do not form a silicide with the silicon.

The metal may include molybdenum.

The conductive protective layer may include a transparent conductive oxide.

The transparent conductive oxide may include at least one selected from IGZO, ITO, and IZO.

The conductive protective layer may have a thickness of 100 Å to 300 Å.

By the fluorine doping, fluorine may be doped into an insulating layer positioned under the amorphous silicon.

During the fluorine doping, fluorine may be positioned on the conductive protective layer.

The insulating layer may be an inorganic layer.

The inorganic layer may include silicon nitride or silicon oxide.

The insulating layer may include an organic layer positioned on the substrate and an inorganic layer positioned on the organic layer and in contact with the amorphous silicon, and the inorganic layer may include silicon oxide.

Fluorine may not be located on the amorphous silicon after removing the conductive protective layer.

Removing the conductive protective layer may be performed by wet etching.

A display device according to an embodiment includes a substrate, an insulating layer on the substrate, a semiconductor layer on the insulating layer, a transistor including the semiconductor layer, and a light emitting device connected to the transistor, wherein the semiconductor layer is crystalline. It includes silicon, and at least one layer of the upper portion of the insulating layer and the semiconductor layer is doped with fluorine.

The insulating layer may include an organic layer in contact with the substrate and an inorganic layer in contact with the semiconductor layer.

The inorganic layer may include silicon nitride or silicon oxide.

The inorganic layer may include a first inorganic layer including silicon nitride and a second inorganic layer including silicon oxide, and the second inorganic layer may directly contact the semiconductor layer.

The thickness of the first inorganic layer may be 200 Å to 500 Å, and the thickness of the second inorganic layer may be 2000 Å to 5000 Å.

According to embodiments, a method for manufacturing a display device preventing generation of static electricity during fluorine doping and a display device manufactured by the method are provided.

### BRIEF DESCRIPTION OF THE DRAWINGS

FIG. 1 is a process flow chart illustrating a manufacturing process of a display device according to an embodiment.

FIG. 2, FIG. 3, FIG. 4, FIG. 5, and FIG. 6 are cross-sectional views illustrating structures formed during a manufacturing process of a display device according to an embodiment.

FIG. 7 illustrates a display device doped with fluorine without including a conductive protective layer.

FIG. 8 is a cross-sectional view of a stacked structure of a display device according to an embodiment.

FIG. 9 schematically illustrates a cross-section of a display device according to an embodiment.

FIG. 10 is an equivalent circuit diagram of one pixel in a display device according to an embodiment.

FIG. 11 is a timing diagram of signals applied to one pixel of the display device according to an embodiment.

FIG. 12 is a layout view of one pixel area of a display device according to an embodiment.

FIG. 13 is a cross-sectional view taken along line X-X′ in FIG. 12.

### DETAILED DESCRIPTION OF THE EMBODIMENTS

Hereinafter, various embodiments of the present disclosure will be described in detail with reference to the accompanying drawings so that a person of an ordinary skill in the art may understand and carry out principles of the present disclosure.

Embodiments of the present disclosure may be embodied in many different forms and are not limited to the specific embodiments set forth herein.

In order to clearly describe the present disclosure, parts irrelevant to the description may be omitted.

The same reference numerals are assigned to the same or similar components throughout the drawings and the specification. In addition, the size and thickness of each component shown in the drawings are shown for convenience of explanation, the present disclosure is not necessarily limited to that which is shown. For example, the thicknesses of various layers and regions shown in the drawing may be shown enlarged or exaggerated to clearly express the various layers and regions.

In addition, when a part such as a layer, film, region, or plate is said to be “above” or “on” another part, this includes not only the case where it is “directly on” the other part, but also the case where another part is in the middle. Conversely, a part said to be “directly on” another part means that there is no other part in between. In addition, being “above” or “on” a reference part means being located above or below the reference part in one orientation and does not necessarily mean being located “above” or “on” it in the opposite direction of gravity.

In addition, throughout the specification, when a certain component is said to “include” and element, it means that the component may further include other elements unless otherwise stated.

In addition, throughout the specification, reference to “planar image,” means when the target part is viewed from above a major surface of the target part, and reference to “cross-sectional image or view” means an image or view of a cut surface of a target part.

Hereinafter, an embodiment of a method of manufacturing a display device and a display device manufactured by the method will be described in detail with reference to drawings.

The manufacturing method according to the present embodiment may be characterized by a fluorine doping process of a semiconductor layer of the display device; hereinafter, the formation of the semiconductor layer and the fluorine doping process will be described.

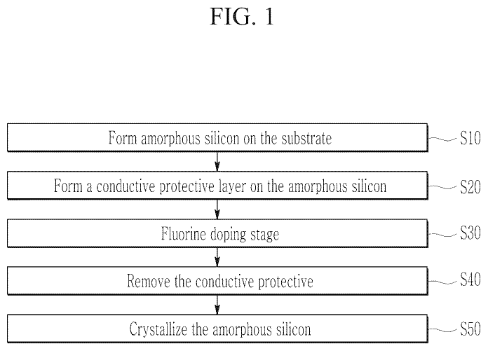

FIG. 1 is a process flow chart illustrating a manufacturing process of a display device according to an embodiment.

Referring to FIG. 1, a method of manufacturing a display device according to the present embodiment includes forming amorphous silicon on a substrate (S10), forming a conductive protective layer on the amorphous silicon (S20), and doping fluorine (S30), removing the conductive protective layer (S40), and crystallizing amorphous silicon (S50). Forming a conductive protective layer (S20) on the semiconductor layer before doping with fluorine (S30) has an important effect. In particular, as described in more detail below, the conductive protective layer may prevent generation of static electricity during the fluorine doping process.

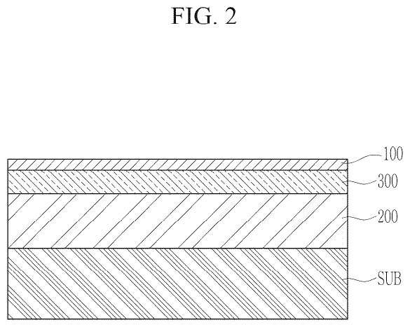

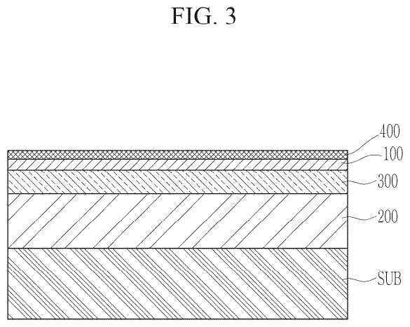

An embodiment of a method for manufacturing a display device will now be described with reference to FIG. 2 to FIG. 6. FIG. 2 to FIG. 6 are cross-sectional views of structures illustrating a manufacturing process of a display device according to an embodiment.

First, referring to FIG. 2, amorphous silicon 100 is formed on a substrate SUB. In the illustrated example, a plurality of layers, specifically an organic layer 200 and an inorganic layer 300, may be positioned between the substrate SUB and the amorphous silicon 100. Although one organic layer 200 and one inorganic layer 300 are shown in FIG. 2, a plurality of organic layers 200 and one or more inorganic layers 300 may be provided. The inorganic layer 300 may be in direct contact with the amorphous silicon 100 or alternatively may be on organic layer 200 as shown in FIG. 2. The organic layer 200 may include polyimide, but this is only an example and is not limited thereto. The inorganic layer 300 may include silicon nitride or silicon oxide.

Next, referring to FIG. 3, a conductive protective layer 400 is formed on the amorphous silicon 100. If the conductive protective layer 400 is directly on the amorphous silicon 100, the conductive protective layer 400 preferably includes a material that does not form silicon and silicide. For example, the conductive protective layer 400 may include molybdenum or a transparent conductive oxide. The transparent conductive oxide may be at least one selected from IGZO, ITO, and IZO but is not limited thereto.

The conductive protective layer 400 may have a thickness between about 100 Å and 300 Å. When the thickness of the conductive protective layer 400 is less than 100 Å, the effect of reducing static electricity may be insignificant, and when the thickness of the conductive protective layer 400 exceeds 300 Å, the time required to remove the conductive protective layer 400 may decrease in productivity of the process.

Next, referring to FIG. 4, fluorine doping is performed. As shown in FIG. 4, fluorine may pass through the conductive protective layer 400 and the amorphous silicon 100 and be doped into the inorganic layer 300 positioned below the amorphous silicon 100. This doping can be done using an accelerating voltage for an ion implantation process, and the applied voltage for the process may be between about 10 KeV and 40 KeV.

The fluorine doping may improve the instantaneous image retention and hysteresis of a transistor to be manufactured later in the process. Hysteresis is a phenomenon in which a shift in the transistor curve occurs due to the occurrence of charge traps in the insulating film due to current and voltage stress of the transistor. However, in the case of the present embodiment, as fluorine may be doped into the insulating film 300, defects in the insulating film 300 may be minimized, thereby improving instantaneous afterimage and hysteresis. More particularly, Si—F bonds may be generated in the insulating film 300 by fluorine doping. When this occurs, since the Si—F bond is more reactive or stronger than the F—F bond, the Si—F bonds may remove defects by removing dangling bonds of Si in the insulating film 300, and thereby provide passivation of the charge trap sites.

A problem with conventional flouring doping processes arises in that static electricity is generated during the fluorine doping process, and static electricity may positively shift a threshold voltage Vth. That is, during doping, local F+ ion concentration may accumulate due to negative (−) static charges, which may cause a positive shift in a threshold voltage. However, since generation of static electricity is prevented by the conductive protective layer 400 in the present embodiment, it is possible to solve the problem of positive shifting of the threshold voltage. That is, the conductive protective layer 400 (being conductive) maintains the same potential as the amorphous silicon 100, does not generate static electricity, and prevents local F+ ion concentration caused by static electricity during the doping process.

As shown in FIG. 4, fluorine may be located on both the upper and lower surfaces of the conductive protective layer 400 during the doping process. That is, some fluorine may pass through the conductive protective layer 400 and be doped into the inorganic film layer 300, and some fluorine may be located on the upper surface of the conductive protective layer 400.

Next, referring to FIG. 5, the conductive protective layer 400 may be removed. The conductive protective layer 400 may be removed, for example, by a wet etching process. Removing the conductive protective layer 400 also removes the fluorine located on the upper surface of the conductive protective layer 400. Further, fluorine is not located on the amorphous silicon 100. This is because the conductive protective layer 400 is removed after the upper surface of the amorphous silicon 100 was covered and protected by the conductive protective layer 400.

Next, referring to FIG. 6, a crystalline silicon 110 is formed by crystallizing the amorphous silicon 100. The crystallization process may be performed, for example, through laser irradiation. Damage caused by earlier fluorine doping can be repaired by this crystallization process. That is, in the present embodiment, the crystallization process can repair damage caused in the doping process because doping is performed prior to the crystallization of the silicon layer. In contrast, if fluorine doping is performed after crystallization of the silicon layer, damage generated during the doping process may not be repaired, or a separate additional process may be required to repair the damage.

As described above, in the manufacturing method of the display device according to the present embodiment, since the conductive protective layer 400 is formed on the amorphous silicon 100 before doping, generation of static electricity can be prevented during doping. Also, since the conductive protective layer 400 is removed after the fluorine doping process, fluorine may not be located on the upper surface of the amorphous silicon 100 or the crystalline silicon 110.

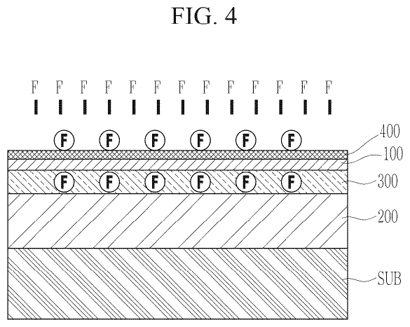

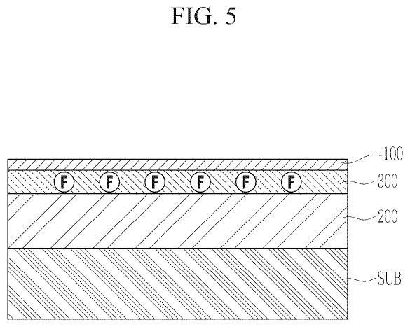

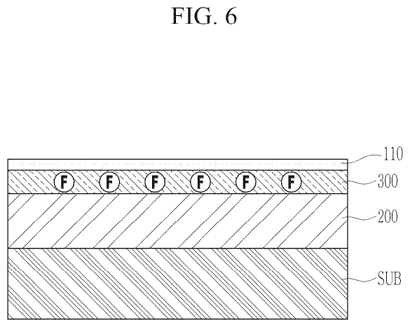

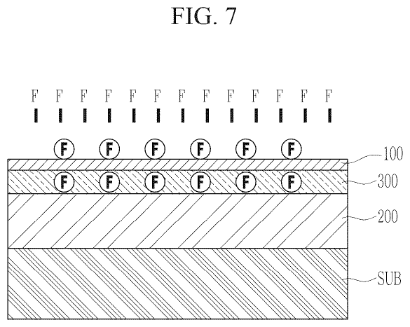

FIG. 7 illustrates a structure formed during a manufacturing process for a display device where the structure is doped with fluorine without including the conductive protective layer 400 described above. Referring to FIG. 7, when doping is performed without the conductive protective layer 400, doped fluorine may be left on both the upper and lower surfaces of the amorphous silicon 100. In contrast, in the embodiment described above, doping was performed after forming the conductive protective layer 400, and then the conductive protective layer 400 was removed, so fluorine is not located on the upper surface of the amorphous silicon 100 or the crystalline silicon 110 of FIG. 5 or FIG. 6.

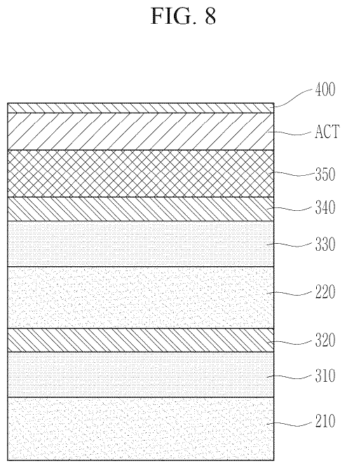

FIG. 8 is a cross-sectional view of a stacked structure in a display device according to an embodiment of the present disclosure. Referring to FIG. 8, the stacked structure includes a first organic layer 210, a first barrier layer 310, a second barrier layer 320, a second organic layer 220, a third barrier layer 330, a first buffer layer 340, a second buffer layer 350, and a semiconductor layer ACT. The semiconductor layer ACT may include crystalline silicon. FIG. 8 may be considered a specific example of the laminated structure of FIG. 2 to FIG. 7, where the organic layer 200 and the inorganic layer 300 shown in FIG. 2 to FIG. 7 includes the first organic layer 210, the first barrier layer 310, the second barrier layer 320, the second organic layer 220, the third barrier layer 330, the first buffer layer 340, and the second buffer layer 350.

In FIG. 8, the first organic layer 210 and the second organic layer 220 may include polyimide. The first barrier layer 310, the second barrier layer 320, the third barrier layer 330, the first buffer layer 340, and the second buffer layer 350 may include silicon nitride or silicon oxide.

In a specific example, the first barrier layer 310 and the third barrier layer 330 may include silicon oxide. The thickness of the first barrier layer 310 and the third barrier layer 330 may be between 4000 Å and 6000 Å. In addition, the second barrier layer 320 may include silicon nitride—particularly, NH₃ Free SiNₓ. The first buffer layer 340 may include silicon nitride and may have a thickness of 200 Å to 500 Å. The second buffer layer 350 may include silicon oxide, and may have a thickness of 2000 Å to 5000 Å.

FIG. 8 the semiconductor layer ACT may directly contact the second buffer layer 350. Due to doping as described above, a layer under the semiconductor layer ACT may contain fluorine. Also, as described above, the conductive protective layer 400 may be positioned on the semiconductor layer ACT during fluorine doping, and the conductive protective layers 400 and fluorine at the interface of the conductive protective layer 400 and semiconductor layer ACT are removed so that fluorine may not be on the semiconductor layer ACT.

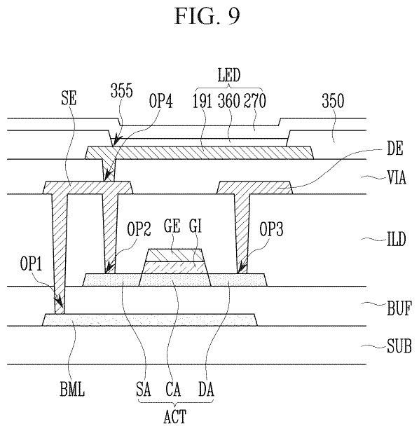

The manufacturing processes described above may be part of a process manufacturing a display device, and FIG. 9 schematically illustrates a cross-section of a display device according to an embodiment. FIG. 9 particularly shows a simplified view of a portion of a cross-section for convenience of explanation, and the present disclosure is not limited thereto.

FIG. 9 shows the substrate SUB. In some embodiments, the substrate (SUB) may contain polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and it may include at least one of cellulose acetate propionate. The substrate SUB may be a rigid substrate or a flexible substrate capable of being bent, folded, or rolled. The substrate SUB may contain a single layer or multiple layers. On the substrate SUB, at least one base layer including a polymer resin and at least one inorganic layer may be sequentially stacked or alternately stacked.

A light blocking layer BML is positioned on the substrate SUB. The light blocking layer BML may contain aluminum (Al), silver (Ag), magnesium (Mg), gold (Au), nickel (Ni), chromium (Cr), calcium (Ca), molybdenum (Mo), titanium (Ti), tungsten (W), copper (Cu) and/or a metal oxide and may have a single layer or multilayer structure including the same.

A buffer layer BUF is positioned on the light blocking layer BML. The buffer layer BUF may include silicon oxide (SiOₓ), silicon nitride (SiNₓ), silicon oxynitride (SiOₓN_{y}), or amorphous silicon (Si). The buffer layer BUF may include a first opening OP1 overlapping a region of the light blocking layer BML. A source electrode SE of an overlying transistor may be connected to the light blocking layer BML through the first opening OP1.

The semiconductor layer ACT is positioned on the buffer layer BUF, and the buffer layer BUF may be doped with fluorine and may include fluorine as described above. In particular, the buffer layer BUF may have been doped with fluorine through a conductive protective layer that is formed on the semiconductor layer ACT before a fluorine doping process and that is removed after the fluorine doping process.

The semiconductor layer ACT may include polycrystalline silicon. The semiconductor layer ACT may include a channel region CA overlapping a gate electrode GE, and a source region SA and a drain region DA positioned on opposite sides of the channel region.

A gate insulating layer GI is positioned on the semiconductor layer ACT. The gate insulating film GI may include silicon oxide (SiOₓ), silicon nitride (SiNₓ), and silicon oxynitride (SiOₓN_{y}), and the gate insulating layer GI may have a single-layer or multi-layer structure including the same. The gate insulating layer GI may be positioned to overlap the channel region CA of the semiconductor layer ACT.

A gate conductive layer including the gate electrode GE may be positioned on the gate insulating layer GI. The gate conductive layer may include molybdenum (Mo), aluminum (Al), copper (Cu), titanium (Ti), or a metal oxide and may have a single-layer or multi-layer structure including the same. The gate electrode GE may be patterned during the same process that patterns the gate insulating layer GI and may have the same planar shape as the gate insulating layer GI. The gate electrode GE may be positioned to overlap the semiconductor layer ACT and the substrate SUB in a direction perpendicular to the plane of the substrate SUB.

An interlayer insulating dielectric ILD may be a layer or film positioned on the semiconductor layer ACT and the gate electrode GE. The interlayer insulating dielectric ILD may include silicon oxide (SiOₓ), silicon nitride (SiNₓ), or silicon oxynitride (SiOₓN_{y}), and the interlayer insulating dielectric ILD may have a single-layer or multi-layer structure including the same. In the case where the interlayer dielectric ILD is a multilayer structure including silicon nitride and silicon oxide, the layer containing silicon nitride may be located closer to the substrate SUB than the layer containing silicon oxide.

The opening OP1 extends through the interlayer insulating dielectric ILD in an area overlapping the light blocking layer BML, and a second opening OP2 through the interlayer insulating dielectric ILD overlaps the source region SA of the semiconductor layer ACT. A third opening OP3 through the interlayer insulating dielectric ILD may be included.

A data conductive layer including the source electrode SE and the drain electrode DE is positioned on the interlayer insulating dielectric ILD. The data conductive layer may contain aluminum (Al), silver (Ag), magnesium (Mg), gold (Au), nickel (Ni), chromium (Cr), calcium (Ca), molybdenum (Mo), titanium (Ti), tungsten (W), copper (Cu), or a metal oxide and may have a single-layer or multi-layer structure including the same. The source electrode SE may contact the light blocking layer BML through the first opening OP1 and contact the source region SA of the semiconductor layer ACT through the second opening OP2. The drain electrode DE may contact the drain region DA of the semiconductor layer ACT through the third opening OP3.

An insulating layer VIA is positioned on the data conductive layer. The insulating film (VIA) may include organic insulating materials such as general-purpose polymers such as polymethylmethacrylate (PMMA) or polystyrene (PS), polymer derivatives having phenolic groups, acrylic polymers, imide polymers, polyimides, and siloxane polymers. The insulating layer VIA may include a fourth opening OP4 overlapping the source electrode SE.

A first electrode 191 is positioned on the insulating layer VIA. A pixel-defining layer 350 is positioned on the insulating film VIA and the first electrode 191. The pixel-defining layer 350 has an opening 355 overlapping the first electrode 191. An emission layer 360 may be positioned within the opening 355 in contact with the first electrode 191. A second electrode 270 may be positioned on the pixel-defining layer 350 and the light emitting layer 360. The first electrode 191, the light emitting layer 360, and the second electrode 270 may constitute a light emitting device LED of a pixel in the display device.

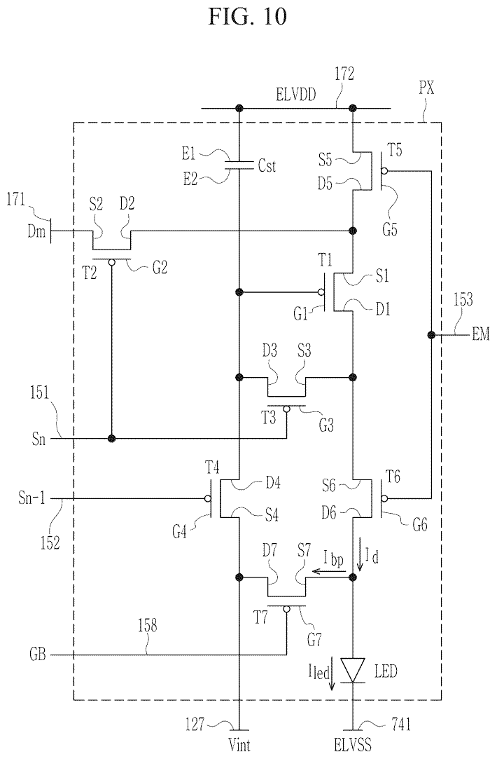

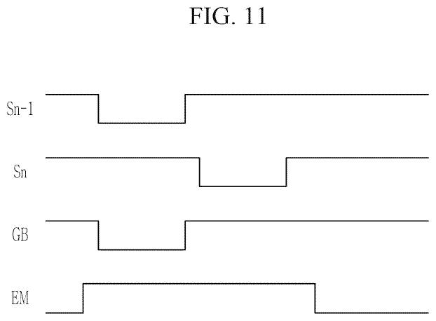

Hereinafter, a structure and operation of a display device according to an embodiment will be described in detail with reference to FIG. 10 and FIG. 11. However, the described structure and operation are only for an example, and the present disclosure is not limited thereto. FIG. 10 is an equivalent circuit diagram of one pixel in the light emitting display device according to an embodiment, and FIG. 11 is a timing diagram of signals applied to one pixel of the light emitting display device according to an embodiment.

Referring to FIG. 10, the pixel PX of the light emitting display device includes multiple transistors T1, T2, T3, T4, T5, T6, and T7 connected to various signal lines 127, 151, 152, 153, 158, 171, 172, and 741, a storage capacitor Cst, and a light emitting element LED. The light emitting display device may include a display area where an image is displayed, and multiple pixels including the pixel PX may be arranged in various forms in the display area.

The transistors T1, T2, T3, T4, T5, T6, and T7 include a driving or first transistor T1, a switching or second transistor T2, and a third transistor T3 connected to the scan line 151, all of which primarily control the magnitude and timing of a current Iled driving the light emitting element LED. The other transistors T4, T5, T6, and T7 are transistors (hereinafter referred to as compensation transistors) are for efficient operation of the light emitting element LED. The compensation transistors T4, T5, T6, and T7 may also be referred to as the fourth transistor T4, the fifth transistor T5, the sixth transistor T6, and the seventh transistor T7.

The plurality of signal lines 127, 151, 152, 153, 158, 171, 172, and 741 connected to the pixel PX include a scan line 151, a previous scan line 152, an emission control line 153, a bypass control line 158, and a data line 171, a driving voltage line 172, an initialization voltage line 127, and a common voltage line 741. The bypass control line 158 may be part of or electrically connected to the previous scan line 152. Alternatively, the bypass control line 158 may be part of or electrically connected to the scan line 151.

The scan line 151, which may be connected to a gate driver (not shown), transmits a scan signal Sn to gates of the second transistor T2 and the third transistor T3.

The previous scan line 152, which may be connected to the gate driver, transfers to a gate of the fourth transistor T4 the previous scan signal Sn−1, which may also be applied to the pixel positioned at the previous stage.

The light emitting control line 153, which may be connected to a light emitting control unit (not shown), transfers the light emitting control signal EM to gates of the fifth transistor T5 and the sixth transistor T6 for controlling the time when the light emitting element LED emits light.

The bypass control line 158 transfers the bypass signal GB to a gate of the seventh transistor T7.

The data line 171 transmits the data voltage Dm generated by a data driver (not shown), and the luminance of the light emitting element LED, which is a light emitting diode in the embodiment of FIG. 10, changes according to the data voltage Dm.

The driving voltage line 172 applies the driving voltage ELVDD. The initialization voltage line 127 transfers the initialization voltage Vint to initialize the driving transistor T1 as described further below. The common voltage line 741 applies the common voltage ELVSS. Constant voltages may be applied to the driving voltage line 172, the initialization voltage line 127, and the common voltage line 741.

Hereinafter, the transistors T1, T2, T3, T4, T5, T6, and T7 in the pixel PX will be further described.

The driving transistor T1 is a transistor that adjusts the amount of the output current Id according to the applied data voltage Dm. In particular, the output driving current Id is applied to the light emitting element LED to adjust the brightness of the light emitting element LED according to the data voltage Dm. To this end, the first electrode S1 of the driving transistor T1 is disposed to receive the driving voltage ELVDD. The first electrode S1 of the driving transistor T1 is connected to the driving voltage line 172 via the fifth transistor T5. In addition, the first electrode S1 of the driving transistor T1 is also connected to the second electrode D2 of the second transistor T2 to receive the data voltage Dm.

The second electrode D1 (output electrode) of the driving transistor T1 is connected to output current toward the light emitting element LED. In the embodiment of FIG. 10, the second electrode D1 of the driving transistor T1 is connected to the anode of the light emitting element LED via the sixth transistor T6.

The gate electrode G1 is connected to one electrode (second storage electrode E2) of the storage capacitor Cst. Accordingly, the voltage of the gate electrode G1 depends on the voltage stored in the storage capacitor Cst, and the driving current Id output from the driving transistor T1 changes accordingly with changes in the voltage stored in the storage capacitor Cst.

The second transistor T2 is a transistor that receives the data voltage Dm into the pixel PX. The gate electrode G2 of the second transistor T2 is connected to the scan line 151, and the first electrode S2 of the second transistor T2 is connected to the data line 171. The second electrode D2 of the second transistor T2 is connected to the first electrode S1 of the driving transistor T1. When the second transistor T2 is turned on according to the scan signal Sn transmitted through the scan line 151, the data voltage Dm transmitted through the data line 171 is applied to the first electrode S1 of the driving transistor T1.

The third transistor T3 is a transistor that transmits a compensation voltage (voltage of Dm+Vth) obtained by changing the data voltage Dm through the driving transistor T1 to the second storage electrode E2 of the storage capacitor Cst. The gate electrode G3 of the third transistor T3 is connected to the scan line 151, and the first electrode S3 of the third transistor T3 is connected to the second electrode D1 of the driving transistor T1. The second electrode D3 of the third transistor T3 is connected to the second storage electrode E2 of the storage capacitor Cst and the gate electrode G1 of the driving transistor T1. The third transistor T3 turns on according to the scan signal Sn received through the scan line 151, connecting the gate electrode G1 of the driving transistor T1 and the second electrode D1 of the driving transistor T1, and also connects the second electrode D1 of the driving transistor T1 and the second storage electrode E2 of the storage capacitor Cst.

The fourth transistor T4 serves to initialize the gate electrode G1 of the driving transistor T1 and the second storage electrode E2 of the storage capacitor Cst. The gate electrode G4 of the fourth transistor T4 is connected to the previous scan line 152, and the first electrode S4 of the fourth transistor T4 is connected to the initialization voltage line 127. The second electrode D4 of the fourth transistor T4 is connected to the second storage electrode E2 of the storage capacitor Cst, the second electrode D3 of the third transistor T3, and the gate electrode G1 of the driving transistor T1. The fourth transistor T4 applies the initialization voltage Vint to the storage capacitor Cst and the gate electrode G1 of the driving transistor T1 according to the previous scan signal Sn−1 transmitted through the previous scan line 152, so that the initialization voltage Vint is transferred to the second storage electrode E2. Accordingly, the gate voltage of the gate electrode G1 of the driving transistor T1 and the storage capacitor Cst may be initialized. The initialization voltage Vint may be a voltage capable of turning on the driving transistor T1, e.g., by having a low voltage value in the example of FIG. 10.

The fifth transistor T5 serves to transmit the driving voltage ELVDD to the driving transistor T1. The gate electrode G5 of the fifth transistor T5 is connected to the emission control line 153, and the first electrode S5 of the fifth transistor T5 is connected to the driving voltage line 172. The second electrode D5 of the fifth transistor T5 is connected to the first electrode S1 of the driving transistor T1.

The sixth transistor T6 serves to transfer the driving current Id output from the driving transistor T1 to the light emitting element LED. The gate electrode G6 of the sixth transistor T6 is connected to the emission control line 153, and the first electrode S6 of the sixth transistor T6 is connected to the second electrode D1 of the driving transistor T1. The second electrode D6 of the sixth transistor T6 is connected to the anode of the light emitting element LED.

The fifth transistor T5 and the sixth transistor T6 turn on simultaneously according to the light control signal EM transmitted through the light control line 153. When the fifth and sixth transistors T5 and T6 turn on, the driving voltage ELVDD is applied to the first electrode S1 of the driving transistor T1 through the fifth transistor T5, and the driving transistor T1 outputs the driving current Id according to the voltage of the gate electrode G1 of the driving transistor T1 (i.e., the voltage of the second storage electrode E2 of the storage capacitor Cst). The output driving current Id is transmitted to the light emitting element LED through the sixth transistor T6. As a result, the current Iled flows through the light emitting element LED, and the light emitting element LED emits light.

The seventh transistor T7 serves to initialize the anode of the light emitting element LED. The gate electrode G7 of the seventh transistor T7 is connected to the bypass control line 158, the first electrode S7 of the seventh transistor T7 is connected to the anode of the light emitting element LED, and the second electrode D7 of the seventh transistor T7 is connected to the initialization voltage line 127. The bypass signal GB may be applied with the same timing as the previous scan signal Sn−1, and the bypass control line 158 may be connected to the previous scan line 152. Alternatively, the bypass control line 158 may transmit a signal GB that is separate from the previous scan signal Sn−1, and the bypass control line 158 may not be connected to the previous scan line 152. When the seventh transistor T7 is turned on according to the bypass signal GB, the initialization voltage Vint is applied to the anode of the light emitting element LED and is initialized.

The first storage electrode E1 of the storage capacitor Cst is connected to the driving voltage line 172, and the second storage electrode E2 is connected to the gate electrode G1 of the driving transistor, the second electrode D3 of the third transistor T3, and the second electrode D4 of the fourth transistor T4. As a result, the second storage electrode E2 of the storage capacitor Cst determines the voltage of the gate electrode G1 of the driving transistor T1. The second storage electrode E2 receives the data voltage Dm through the second electrode D3 of the third transistor T3 when the first, second, and third transistors T1, T2, and T3 are turned on while the fifth and sixth transistors T5 and T6 are turned off. The storage electrode E2 receives the initialization voltage Vint through the second electrode D4 of the fourth transistor T4 when the fourth transistor T4 is turned on.

The anode of the light emitting element LED is connected to the second electrode D6 of the sixth transistor T6 and the first electrode S7 of the seventh transistor T7. The cathode of the light emitting element LED receives the common voltage ELVSS from the common voltage line 741.

In the embodiment of FIG. 10, the pixel circuit includes seven transistors T1 to T7 and one capacitor Cst, but embodiments in accordance with the present disclosure are not limited thereto, and the number of transistors, capacitors, and their connections can be variously changed.

The operation of one pixel of a light emitting display device according to an embodiment will be described with reference to FIG. 10 and FIG. 11.

During an initialization period, the low-level previous scan signal Sn−1 is supplied to the pixel PX through the previous scan line 152. This turns on the fourth transistor T4, which applies the initialization voltage Vint to the gate electrode G1 of the driving transistor T1 and the second storage electrode E2 of the storage capacitor Cst through the fourth transistor T4. As a result, the driving transistor T1 and the storage capacitor Cst are initialized. When the voltage of the initialization voltage Vint is low, the driving transistor T1 may be turned on.

During the initialization period, the low-level bypass signal GB is also applied to the seventh transistor T7. The seventh transistor T7 then turns on and applies the initialization voltage Vint to the anode of the light emitting element LED. As a result, the anode of the light emitting element (LED) is also initialized.

After the initialization period, the voltage of the low-level previous scan signal Sn−1 and the bypass signal GB is raised, and the low-level scan signal Sn is supplied to the pixel PX through the scan line 151 during a data writing period. The second transistor T2 and the third transistor T3 are turned on by the low-level scan signal Sn. When the second transistor T2 is turned on, the data voltage Dm passes through the second transistor T2 and is input to the first electrode S1 of the driving transistor T1.

Also, during the data writing period, the third transistor T3 is turned on, and as a result, the second electrode D1 of the driving transistor T1 is electrically connected to the gate electrode G1 and the second storage electrode E2 of the storage capacitor Cst. The gate electrode G1 and the second electrode D1 of the driving transistor T1 are connected to form a diode connection. In addition, the driving transistor T1 is turned on because a low voltage (initialization voltage Vint) was applied to the gate electrode G1 during the initialization period. As a result, the data voltage Dm input to the first electrode S1 of the driving transistor T1 passes through the channel of the driving transistor T1, is output from the second electrode D1, passes through the third transistor T3, and is stored in the second storage electrode E2 of the storage capacitor Cst. Transmission through the driving transistor T1 changes the voltage applied to the second storage electrode E2 according to the threshold voltage Vth of the driving transistor T1. In particular, the data voltage Dm is applied to the first electrode S1 of the driving transistor T1, and when the initialization voltage Vint is applied to the gate electrode G1 of the driving transistor T1, the voltage output to the second electrode D1 may be Vgs+Vth. Here, since Vgs is the difference between the voltage applied to the gate electrode G1 and the first electrode S1 of the driving transistor T1, Vgs may have a value of Dm-Vint. Therefore, the voltage output from the second electrode D1, which is stored in the second storage electrode E2, may have a value of Dm−Vint+Vth.

After that, during a light emission period, the emission control signal EM supplied from the emission control line 153 drops to a low-level value, and the fifth transistor T5 and the sixth transistor T6 are turned on. As a result, the driving voltage ELVDD is applied to the first electrode S1 of the driving transistor T1, and the second electrode D1 of the driving transistor T1 is connected to the light emitting element LED. The driving transistor T1 generates a driving current Id according to a voltage difference between the voltage of the gate electrode G1 and the voltage of the first electrode S1 (i.e., the driving voltage ELVDD). The driving current Id of the driving transistor T1 may have a value proportional to the square of Vgs-Vth. Here, the value of Vgs is the same as the voltage difference across the storage capacitor Cst, and since the value of Vgs is the value of Vg-Vs, it has a value of Dm-Vint+Vth-ELVDD. Here, if the value of Vgs-Vth is obtained by subtracting the value of Vth, the value of Dm-Vint-ELVDD is obtained. That is, the driving current Id of the driving transistor T1 has a current independent of the threshold voltage Vth of the driving transistor T1 as an output. Therefore, even if the driving transistors T1 in different pixels PX have different threshold voltages Vth due to process variation, the output current of the driving transistor T1 can be kept constant, thereby improving the uniformity of characteristics.

In the above calculation formula, the value of Vth may have a value slightly greater than 0 or a negative value in the case of a P-type transistor using a polycrystalline semiconductor. In addition, expressions of + and − may be changed according to the direction in which the voltage is calculated. However, there is no change in the fact that the driving current Id, which is the output current of the driving transistor T1, can have a value independent of the threshold voltage Vth.

When the light emission period ends, an initialization period may begin again, and the same operation of the pixel PX as described above is repeated from the beginning.

One of the first and second electrodes of each of the transistors T1, T2, T3, T4, T5, T6, and T7 may be a source electrode, and the other may be a drain electrode according to a direction in which voltage or current is applied.

According to the above-described embodiment, the seventh transistor T7 in the initialization section can initialize the anode of the light emitting element LED, which may prevent a small amount of current emitted under the condition that the driving transistor T1 is not actually turned on from flowing towards the light-emitting element LED. At this time, a small amount of current may be discharged as bypass current Ibp to the initialization voltage Vint terminal through the seventh transistor T7. As a result, the light emitting device LED does not emit unnecessary light, so that a black gradation can be more clearly displayed, and a contrast ratio can be improved. In this case, the bypass signal GB may have a timing different from that of the previous scan signal Sn−1.

Depending on the embodiment, the seventh transistor T7 may be omitted.

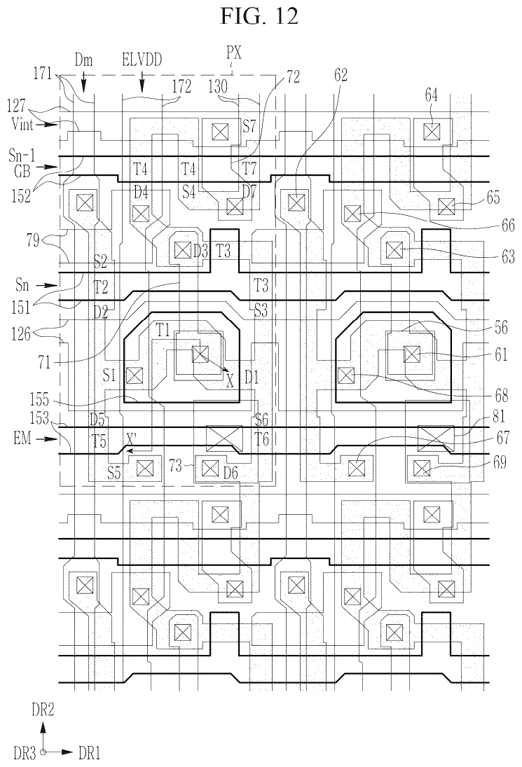

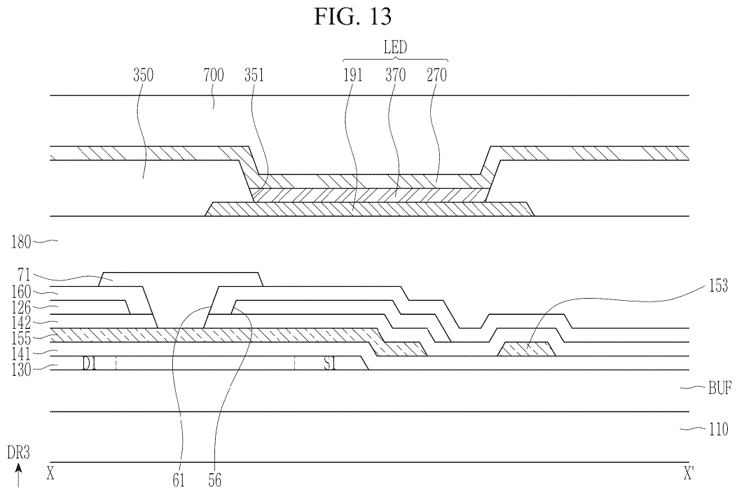

Hereinafter, pixels of a light emitting display device according to an embodiment of FIG. 10 and FIG. 11 will be described with reference to FIG. 12 and FIG. 13. FIG. 12 shows a layout including a pixel area of a light emitting display device according to an embodiment, and FIG. 13 is a cross-sectional view taken along line X-X′ in FIG. 12.

Referring to FIG. 12, the light emitting display device according to an embodiment includes the scan line 151 extending along a first direction DR1 and transmitting the scan signal Sn, and the scan line 152 transmitting the previous scan signal Sn−1. In the illustrated example, the bypass signal GB is also transferred through the previous scan line 152. The illustrated layout further includes the emission control line 153 that transmits the emission control signal EM, and the initialization voltage line 127 that transmits the initialization voltage Vint.

The light emitting display device includes the data line 171 and the driving voltage line 172 extending along the second direction DR2 perpendicular to the first direction DR1. The data line 171 transmits the data voltage Dm, and the driving voltage line 172 transmits the driving voltage ELVDD.

The light emitting display device further includes the driving transistor T1, the second transistor T2, the third transistor T3, the fourth transistor T4, the fifth transistor T5, the sixth transistor T6, and the seventh transistor T7, the storage capacitor Cst, and the light emitting element LED. The channels of each of the driving transistor T1, the second transistor T2, the third transistor T3, the fourth transistor T4, the fifth transistor T5, the sixth transistor T6, and the seventh transistor T7 are located within a semiconductor layer 130 that is extended long. In addition, at least some of the first electrodes and the second electrodes of the plurality of transistors T1, T2, T3, T4, T5, T6, and T7 are also located on the semiconductor layer 130. The semiconductor layer 130 (shaded portion in FIG. 12) may be patterned to bends and regions in various shapes. The semiconductor layer 130 may include a polycrystalline semiconductor such as polysilicon or an oxide semiconductor.

A region of the semiconductor layer 130 forming a transistor may include a channel doped with an n-type impurity or a p-type impurity, and a first doped region and a second doped region located on opposite sides of the channel and having a higher doping concentration than the doped impurities in the channel. The first doped region and the second doped region may correspond to the first electrode and the second electrode, respectively, of the transistor T1, T2, T3, T4, T5, T6, or T7. When one of the first doped region and the second doped region is a source region, the other may be a drain region. In addition, regions of the semiconductor layer between the first and second electrodes of different transistors in the semiconductor layer 130 may be doped so that the two transistors are electrically connected to each other.

Each of the channels of the plurality of transistors T1, T2, T3, T4, T5, T6, and T7 overlaps the gate electrode of the transistor T1, T2, T3, T4, T5, T6, or T7, and the gate electrode of each transistor T1, T2, T3, T4, T5, T6, and T7 may overlie the channel located between the first electrode and the second electrode of the transistor T1, T2, T3, T4, T5, T6, or T7. The plurality of transistors T1, T2, T3, T4, T5, T6, and T7 may have substantially the same stacked structure.

Hereinafter, the driving transistor T1 will be described in detail, and the remaining transistors T2, T3, T4, T5, T6, and T7 will be briefly described. The driving transistor T1 includes a channel, a first gate electrode 155, the first electrode S1 and the second electrode D1. The channel of the driving transistor T1 is between the first electrode S1 and the second electrode D1 and overlaps the first gate electrode 155 in the plan view of FIG. 12. Conversely, the first gate electrode 155 overlaps the channel. The first electrode S1 and the second electrode D1 are respectively positioned on opposite sides of the channel.

An extended portion of the storage line 126 is insulated and positioned above the first gate electrode 155. The extended portion of the storage line 126 overlaps in the plan view with the gate electrode 155, and the second gate insulating layer is interposed therebetween to form a storage capacitor Cst. The extended portion of the storage line 126 is the first storage electrode (E1 in FIG. 10) of the storage capacitor Cst, and the first gate electrode 155 forms the second storage electrode (E2 in FIG. 10).

An opening 56 is formed in the extended portion of the storage line 126 so that the first gate electrode 155 can be connected to a first data connection member 71. An upper surface of the first gate electrode 155 within the opening 56 and the first data connection member 71 are electrically connected through a contact hole 61. The first data connection member 71 is connected to the second electrode D3 of the third transistor T3 to form the gate electrode 155 of the driving transistor T1 and the second electrode D3 of the third transistor T3.

A gate electrode of the second transistor T2 may be part of the scan line 151. A data line 171 is connected to the first electrode S2 of the second transistor T2 through a contact hole 62. The first electrode S2 and the second electrode D2 of the second transistor T2 may be positioned on the semiconductor layer 130.

The third transistor T3 may include two adjacent transistors. In the pixel PX of FIG. 12, the T3 mark is shown on the left side and the bottom side of a bent portion of the semiconductor layer 130. Each of these two parts serves as a third transistor T3, and the first electrode S3 of one third transistor T3 is connected to the second electrode D3 of the other third transistor T3. The gate electrodes of the two transistors T3 may be part of the scan line 151 or a part protruding upward from the scan line 151. Such a structure may be referred to as a dual-gate structure and may serve to block leakage current. The first electrode S3 of the third transistor T3 is connected to the first electrode S6 of the sixth transistor T6 and the second electrode D1 of the driving transistor T1. The second electrode D3 of the third transistor T3 is connected to the first data connection member 71 through a contact hole 63.

The fourth transistor T4 also includes two fourth transistors T4, and the two fourth transistors T4 are formed where the previous scan line 152 and the semiconductor layer 130 meet. A gate electrode of the fourth transistor T4 may be part of the previous scan line 152. The first electrode S4 of one fourth transistor T4 is connected to the second electrode D4 of the other fourth transistor T4. Such a structure may be referred to as a dual-gate structure and may serve to block leakage current. The second data connection member 72 is connected to the first electrode S4 of the fourth transistor T4 through a contact hole 65, and the second electrode D4 of the fourth transistor T4, the data connection member 71 is connected through the contact hole 63.

As described above, by using the dual-gate structure for the third transistor T3 and the fourth transistor T4, leakage current can be effectively prevented from being generated by blocking the electron movement path of the channel in the off state.

A gate electrode of the fifth transistor T5 may be part of the emission control line 153. The driving voltage line 172 is connected to the first electrode S5 of the fifth transistor T5 through a contact hole 67, and the second electrode D5 connects to the first electrode S1 of the driving transistor T1 through the semiconductor layer 130.

A gate electrode of the sixth transistor T6 may be part of the emission control line 153. The second electrode D6 of the sixth transistor T6 is connected through the third data connection member 73 via a contact hole 69, and the first electrode S6 is connected to the second electrode D1 of the driving transistor T1 through the semiconductor layer 130.

A gate electrode of the seventh transistor T7 may be part of the previous scan line 152. The first electrode S7 of the seventh transistor T7 is connected to the second electrode D6 of the sixth transistor T6, and the second electrode D7 is connected to the first electrode S4 of the fourth transistor T4.

The storage capacitor Cst includes a first storage electrode E1 and a second storage electrode E2 overlapping each other with the second gate insulating layer 142 interposed therebetween. The second storage electrode E2 corresponds to the gate electrode 155 of the driving transistor T1, and the first storage electrode E1 may be an extended portion of the storage line 126. Here, the second gate insulating layer 142 becomes a dielectric, and capacitance is determined by the charge stored in the storage capacitor Cst and the voltage between the first and second storage electrodes E1 and E2. By using the first gate electrode 155 as the second storage electrode E2, it is possible to secure space to form a storage capacitor Cst in a narrowed area by the channel of the driving transistor T1 that occupies a large area within the pixel. A driving voltage line 172 is connected to the first storage electrode E1 through a contact hole 68. Therefore, the storage capacitor Cst stores charge corresponding to the difference between the driving voltage ELVDD transmitted to the first storage electrode E1 through the driving voltage line 172 and the gate voltage Vg of the gate electrode 155.

The second data connection member 72 is connected to the initialization voltage line 127 through the contact hole 64.

A first electrode of the light emitting element is connected to the third data connection member 73 through the contact hole 81. The first electrode may be a pixel electrode.

A parasitic capacitor control pattern 79 may be positioned between the dual-gate electrodes of the compensation transistor T3. A parasitic capacitor exists in a pixel, and if the voltage applied to the parasitic capacitor changes, the image quality characteristics also may change. The driving voltage line 172 is connected to the parasitic capacitor control pattern 79 through a contact hole 66. Accordingly, it is possible to prevent the image quality characteristics from being changed by applying the driving voltage ELVDD, which is a constant DC voltage, to the parasitic capacitor. The parasitic capacitor control pattern 79 may be positioned in a region different from that shown, and a voltage other than the driving voltage ELVDD may be applied.

One end of the first data connection member 71 is connected to the gate electrode 155 through the contact hole 61, and the other end is connected to the second electrode D3 of the third transistor T3 through the contact hole 63, it is connected to the second electrode D4 of the fourth transistor T4.

One end of the second data connection member 72 is connected to the first electrode S4 of the fourth transistor T4 through the contact hole 65, and the other end is connected to the initialization voltage line 127 through the contact hole 64.

The third data connection member 73 is connected to the second electrode of the sixth transistor T6 through the contact hole 69.

Hereinafter, a cross-sectional structure of a light emitting display device according to an embodiment will be described in a stacking order with reference to FIG. 12 and FIG. 13.

The light emitting display device according to an embodiment includes the substrate 110. The substrate 110 may include a plastic layer and a barrier layer. The plastic layer and the barrier layer may have a form in which they are alternately stacked. The plastic layer can include a material selected from a group consisting of polyethersulphone (PES), polyacrylate (PAR), polyetherimide (PEI), polyethylene naphthalate (PEN), polyethylene terephthalate (PET), polyphenylene sulfide (PPS), polyallylate, polyimide (PI), polycarbonate (PC), poly(arylene ether sulfone), and combinations thereof. The barrier layer may include at least one of silicon oxide, silicon nitride, and aluminum oxide, but is not limited thereto and may include any inorganic material.

The buffer layer BUF may be positioned on the substrate 110. The buffer layer BUF may include an inorganic insulating material such as silicon oxide, silicon nitride, or aluminum oxide or may include an organic insulating material such as polyimide acrylic. As described above, the buffer layer BUF may be doped with fluorine and may contain fluorine.

The semiconductor layer 130 including channels, first electrodes, and second electrodes of the transistors T1, T2, T3, T4, T5, T6, and T7 is positioned on the buffer layer BUF.

The first gate insulating layer 141 covering the semiconductor layer 130 is positioned on the semiconductor layer.

A first gate conductor, which includes the first gate electrode 155, the scan line 151, the previous scan line 152, and the emission control line 153, is positioned on the first gate insulating layer 141.

A second gate insulating layer 142 covering the first gate conductor is positioned on the first gate conductor.

The first gate insulating layer 141 and the second gate insulating layer 142 may include an inorganic insulating material or an organic insulating material such as silicon nitride, silicon oxide, and aluminum oxide.

A second gate conductor, which includes the storage line 126, the initialization voltage line 127, and the parasitic capacitor control pattern 79, is positioned on the second gate insulating layer 142.

The interlayer insulating layer 160 covering the second gate conductor is positioned on the second gate conductor. The interlayer insulating layer 160 may include an inorganic insulating material such as silicon nitride, silicon oxide, and aluminum oxide or an organic insulating material.

Above the interlayer insulating layer 160 is located a data conductor including the data line 171, the drive voltage line 172, the first data connection member 71, the second data connection member 72, and the third data connection member 73. The first data connection member 71 may be connected to the first gate electrode 155 through the contact hole 61.

The passivation layer 180 covering the data conductor is positioned on the data conductor. The passivation layer 180 may be a planarization layer and may include an organic insulating material or an inorganic insulating material.

The first electrode 191 is positioned on the passivation layer 180. The first electrode 191 is connected to the third data connection member 73 through a contact hole 81 formed in the passivation layer 180.

The pixel-defining layer 350 is positioned on the passivation layer 180 and the first electrode 191. The pixel-defining layer 350 has an opening 351 overlapping the first electrode 191. The light emitting layer 370 is positioned in the opening 351. The second electrode 270 is positioned on the light emitting layer 370 and the pixel-defining layer 350. The first electrode 191, the light emitting layer 370, and the second electrode 270 form a light emitting element LED.

The first electrode 191 may be a pixel electrode, and the second electrode 270 may be a common electrode. Depending on the embodiment, the pixel electrode may be an anode that is a hole injection electrode, and the common electrode may be a cathode that is an electron injection electrode. Conversely, the pixel electrode may be a cathode, and the common electrode may be an anode. When holes and electrons are injected into the light emitting layer 370 from the pixel electrode and the common electrode, respectively, excitons coupled with the injected holes and electrons emit light when they fall from an excited state to a ground state.

An encapsulation layer 700 protecting the light emitting element LED is positioned on the second electrode 270. As shown, the encapsulation layer 700 may contact the second electrode 270, but the encapsulation layer 700 may alternatively be spaced apart from the second electrode 270 depending on the embodiment. The encapsulation layer 700 may be a thin film encapsulation layer in which inorganic and organic layers are stacked and may include a triple layer composed of an inorganic layer, an organic layer, and an inorganic layer. Depending on the embodiment, a capping layer and a functional layer may be positioned between the second electrode 270 and the encapsulation layer 700.

Although specific embodiments have been described in detail above, the scope of the present disclosure is not limited thereto, and various modifications and improvements made by those skilled in the art using the concepts disclosed herein and defined in the following claims are also included in the scope of the following claims.

What is claimed is:

1. A method of manufacturing a display device, comprising:
forming amorphous silicon on a substrate;
forming a conductive protective layer on the amorphous silicon;
doping with fluorine; and
removing the conductive protective layer.

2. The method of claim 1, further comprising:
crystallizing the amorphous silicon after removing the conductive protective layer.

3. The method of claim 1, wherein:
the conductive protective layer includes a metal that does not form a silicide with the amorphous silicon.

4. The method of claim 3, wherein:
the metal includes molybdenum.

5. The method of claim 1, wherein:
the conductive protective layer includes a transparent conductive oxide.

6. The method of claim 5, wherein:
the transparent conductive oxide includes at least one selected from IGZO, ITO, and IZO.

7. The method of claim 1, wherein:
the thickness of the conductive protective layer is between 100 Å and 300 Å.

8. The method of claim 1, further comprising forming an insulating film on the substrate prior to forming the amorphous silicon on the substrate.

9. The method of claim 8, wherein:
the doping with fluorine dopes fluorine into the insulating layer disposed under the amorphous silicon.

10. The method of claim 9, wherein:
fluorine is positioned on the conductive protective layer when fluorine is doped.

11. The method of claim 8, wherein the insulating film is an inorganic film.

12. The method of claim 11, wherein:
the inorganic film includes silicon nitride or silicon oxide.

13. The method of claim 8, wherein:
the insulating film includes an organic layer on the substrate, and an inorganic layer on the organic layer and in contact with the amorphous silicon; and
the inorganic layer includes silicon oxide.

14. The method of claim 1, wherein after removing the conductive protective layer, fluorine is not positioned on the amorphous silicon.

15. The method of claim 1, wherein the removing of the conductive protective layer is performed by wet etching.

16. A display device, comprising:
a substrate;
an insulating film positioned on the substrate;
a semiconductor layer located on the insulating film;
a transistor comprising the semiconductor layer; and
a light emitting element connected to the transistor, wherein:
the semiconductor layer includes crystalline silicon, and
at least one layer of the insulating layer and the upper portion of the semiconductor layer is doped with fluorine.

17. The display device of claim 16, wherein:
the insulating film includes an organic film in contact with the substrate; and
an inorganic film is in contact with the semiconductor layer.

18. The display device of claim 17, wherein:
the inorganic layer includes silicon nitride or silicon oxide.

19. The display device of claim 18, wherein:
the inorganic layer includes a first inorganic layer including silicon nitride and a second inorganic film containing silicon oxide; and
the second inorganic film and the semiconductor layer are in direct contact.

20. The display device of claim 19, wherein:
the thickness of the first inorganic layer is 200 Å to 500 Å, and
the thickness of the second inorganic film is 2000 Å to 5000 Å.
